(19) United States
(12) Patent Application Publication
(10) Pub. No.: US 2026/0173769 A1
(43) Pub. Date: Jun. 18, 2026

(54) A METHOD OF PRODUCING AN ELECTRONIC DEVICE PRECURSOR

(71) Applicant: Paragraf Limited, Somersham (GB)

(72) Inventors: Rosie Baines, Somersham (GB); Hugh Frederick John Glass, Somersham (GB); Jaspreet Kainth, Somersham (GB); Simon Buttress, Somersham (GB)

(73) Assignee: Paragraf Limited, Somersham (GB)

(21) Appl. No.: 18/702,555

(22) PCT Filed: Oct. 13, 2022
(86) PCT No.: PCT/GB2022/052601

§ 371 Date: Apr. 18, 2024

(30) Foreign Application Priority Data
Oct. 21, 2021 (GB) 2115100.6
Mar. 10, 2022 (GB) 2203362.5
Aug. 31, 2022 (GB) 2212650.2
Aug. 31, 2022 (GB) 2212651.0
Sep. 23, 2022 (GB) 2213912.5

(51) Int. Cl. H10N 52/85; H10N 52/01; H10P 50/00

(52) U.S. Cl. CPC H10N 52/85; H10N 52/01; H10P 50/71; H10P 50/73

(57) ABSTRACT

There is provided a method of producing an electronic device precursor, in particular a method which comprises forming ohmic contacts on the substrate, each in contact with an edge portion of a dielectric-material-capped graphene layer structure, and coating the contacts, and at least one region of the capped structure, with a further dielectric material. The present invention also provides an electronic device precursor comprising a dielectric-material-capped graphene layer structure. The electronic device precursor is preferably for a Hall effect sensor.

The present invention provides a method of producing an electronic device precursor. In particular, a method which comprises forming ohmic contacts on the substrate, each in contact with an edge portion of a dielectric-material-capped graphene layer structure, and coating the contacts, and at least one region of the capped structure, with a further dielectric material. The present invention also provides an electronic device precursor comprising a dielectric-material-capped graphene layer structure. More specifically, the capped structure has an area of 20 mm² or less. Most preferably, the electronic device precursor is for a Hall-effect sensor.

Two-dimensional (2D) materials, in particular graphene, are currently the focus of intense research and development worldwide. 2D-materials have been shown to have extraordinary properties, both in theory and in practice which has led to a deluge of products incorporating such materials which include coatings, batteries and sensors to name but a few. Graphene is most prominent and is being investigated for a range of potential applications. Most notable is the use of graphene in electronic devices and their constituent components and includes transistors, LEDs, photovoltaic cells, Hall-effect sensors, diodes and the like.

Accordingly, there are a wide range of electronic devices known in the prior art which have integrated graphene layer structures (single layer or multi-layer graphene) and/or other 2D-materials as key materials for delivering improvements in such devices over earlier devices and electronic products. These include structural improvements through the use of thinner and lighter materials (which can give rise to flexible electronics) as well as performance improvements such as increased electrical and thermal conductance leading to greater operating efficiencies.

However, due to the sensitivity of exposed 2D-materials to atmospheric interaction and contamination, it is necessary to encapsulate the 2D-material and/or the device comprising such materials with a protective layer or layers. The inventors have found that the metal present in ohmic contacts, necessary for forming electrical connections to the 2D-material, can result in undesirable doping. Doping of 2D-materials results in a modification of the electronic properties. For devices such as Hall-effect sensors (also known as Hall-sensors), device operation is highly sensitive to the change in electronic structure due to the reliance on maintaining as close to charge neutrality in the 2D-material as possible. Nevertheless, contamination from oxygen or water vapour in the atmosphere can lead to a degradation in device performance over time which is undesirable for customers/consumers who expect electronic devices to maintain a specified level of performance for many years after manufacture. Moreover, it can be impossible, or at least very difficult, to retrospectively replace electronic components, particularly microelectronic components and as such, even minor improvements in lifetime and performance stability are highly valued.

“The Dependence of the High-Frequency Performance of Graphene Field-Effect Transistors on Channel Transport Properties”, Asad et al. Journal of the Electron Devices Society, 8, 2020, 457-464 discloses a graphene filed effect transistor comprising an Al₂O₃ dielectric layer. The layer is deposited in accordance with “Graphene Field-Effect Transistors With High Extrinsic f_{T} and fₘₐₓ”, Bonmann et al. IEEE Electron Device Letters, 40, 2019, 131-134 whereby AI metal is evaporated and oxidised by baking on a hotplate.

CN 103985762 discloses an ultralow ohmic contact resistance graphene transistor. The method disclosed therein comprises patterning a dielectric layer with a photoresist and etching the dielectric layer using wet chemistry techniques (e.g. buffered oxide etch (BOE) or a mixture of nitric acid and hydrogen peroxide (HNO₃+H₂O₂)). In one example, AI is deposited on graphene and auto-oxidised to form Al₂O₃ as the dielectric layer.

CN 112038215 discloses a graphene carrier regulation method and graphene quantum Hall device. The method comprises forming a spacer layer on graphene, for example formed of PMMA, PC, ABS or silicone material, and a mixed layer is a ZEP520 resist mixed with F₄TCNQ. In the method, the mixed layer can diffuse through the spacer layer to absorb and transfer charges.

“Magnetotransport in heterostructures of transition metal dichalcogenides and graphene, Völkl et al. Physical Review B, 96, 2017, 125405 relates to a van der Waals pickup technique to fabricate different heterostructures containing WSe₂(WS₂) and graphene. For measurements of the magnetoconductivity of the devices, different backgate voltages are required to establish a mean charge carrier concentration of 1.0×10¹² cm⁻².

There remains a need for a method which allows for the production of an electronic device precursor that comprises a 2D-material layer, and which avoids surface contamination as well as doping by the ohmic contact deposition. There also remains a need for a method capable of encapsulating the 2D-material whilst also allowing for the provision of at least one ohmic contact whilst benefiting from the unique qualities of the 2D-material which are diminished by known processing techniques, in particular so as to provide devices with improved sensitivity.

One such method and product which seeks to address these problems is described in UK Patent Application No. 2020131.5 and International Patent Application No. PCT/EP2021/086642 (the contents of which are incorporated herein by reference in their entirety). The inventors had developed a process which relied on physical vapour deposition of a dielectric material to circumvent some of the problems associated with conventional photolithographic processes. Organic polymer coatings and photoresists are known to be detrimental to graphene and invariably leave residues on the graphene surface, or require undesirably harsh solvents, which can compromise product quality meaning it is desirable to minimise or otherwise completely avoid their use.

The present inventors have further developed a method addressing these problems in the art that comprises protecting a graphene layer structure on a substrate using a dielectric material to both define an etching pattern of the graphene layer and serve as a protective coating in the final device precursor (and of course ultimately in a device). The inventors have found that this provides an intermediate which leaves only the edges of the graphene layer exposed and an ohmic contact may be formed in direct contact with a portion of the exposed edge of the graphene. More specifically, the dielectric is patterned using photolithography which the inventors have found enables the production of much smaller devices than those which are made using physical vapour deposition techniques. Since the dielectric material is not removed from the surface of the graphene which forms part of the product, the graphene is protected during photolithography overcoming the associated problems.

In a first aspect, the present invention provides a method of producing an electronic device precursor, the method comprising:
(i) providing a substrate having a graphene layer structure on and across a surface thereof;
(ii) forming a first layer of dielectric material on and across the graphene layer structure by ALD;
(iii) forming a first patterned resist on the first layer of dielectric material to provide at least one protected region of dielectric material and underlying graphene, and at least one unprotected region of dielectric material and underlying graphene;
(iv) etching away the at least one unprotected region to expose one or more corresponding portions of the substrate and thereby define at least one region of dielectric-material-capped graphene layer structure having one or more exposed edges;
(v) forming a second patterned resist on or over the regions of dielectric-material-capped graphene layer structure and on sub-portions of the exposed portions of the substrate to define contact portions adjacent the one or more exposed edges;
(vi) forming ohmic contacts in the contact portions;
(vii) exposing the dielectric material of the dielectric-material-capped graphene layer structure portions by removing substantially all resist material; and
(viii) forming a second layer of dielectric material on and across the at least one region of dielectric-material-capped graphene layer structure, the ohmic contacts and at least an adjacent portion of the substrate.
In a second aspect, the present invention provides an alternative method to the first aspect for addressing the same problems and for producing the same electronic device precursor, the method comprising:
(I) providing a substrate having a graphene layer structure on and across a surface thereof;
(II) forming a first layer of dielectric material on and across the graphene layer structure by ALD;
(III) forming a first patterned resist on the first layer of dielectric material to provide one protected region of dielectric material and underlying graphene, and a plurality of unprotected regions of dielectric material and underlying graphene;
(IV) etching away the plurality of unprotected regions to expose corresponding portions of the substrate and thereby define one first region of dielectric-material-capped graphene layer structure having a plurality of exposed edges and to define contact portions adjacent the one or more exposed edges;
(V) forming ohmic contacts in the contact portions;
(VI) exposing the dielectric material of the dielectric-material-capped graphene layer structure region by removing substantially all resist material;
(VII) forming a second patterned resist on the first region of dielectric-material-capped graphene layer structure, and optionally the ohmic contacts, to provide at least one protected region of dielectric material and underlying graphene adjacent a plurality of the ohmic contacts, and at least one unprotected region of dielectric material and underlying graphene;
(VIII) etching away the at least one unprotected region to expose one or more corresponding portions of the substrate and thereby define at least one second region of dielectric-material-capped graphene layer structure having a plurality of exposed edges whereby each ohmic contact remains adjacent an edge of the at least one second region of dielectric-material-capped graphene layer structure;
(IX) exposing the dielectric material of the at least one second region of dielectric-material-capped graphene layer structure by removing substantially all resist material;
(X) forming a second layer of dielectric material on and across the at least one second region of dielectric-material-capped graphene layer structure, the ohmic contacts and at least an adjacent portion of the substrate.

The methods provide an electronic device precursor which comprises graphene which exhibits the unique properties desired for electronic devices, and furthermore, properties which are stable over device lifetime. In particular, the inventors were able to provide these advantages by both forming the layer of dielectric material by ALD, and forming a second layer of dielectric material thereon after contact formation. These benefits are critical for commercially produced devices such as Hall-sensors. The first and second aspect differ in the order in which (a) the graphene and dielectric are patterned and (b) the deposition of the ohmic contacts. In the first aspect, the graphene and dielectric are patterned in one process before contact deposition. The contact deposition is then defined by a photoresist. In the second aspect, the graphene and dielectric are preliminarily patterned to define the portions of the substrate for the contacts. After contact deposition, the graphene and dielectric are again patterned into their final shape whilst each shape retains contact with the desired ohmic contacts. Crucially, both methods share the specifics of forming a first dielectric layer on graphene by ALD and produce the same product, at least once the second dielectric layer is formed.

The present disclosure will now be described further. In the following passages, different aspects/embodiments of the disclosure are defined in more detail. Each aspect/embodiment so defined may be combined with any other aspect/embodiment or aspects/embodiments unless clearly indicated to the contrary. In particular, any feature indicated as being preferred or advantageous may be combined with any other feature or features indicated as being preferred or advantageous.

The first and second aspects each relate to a method of manufacturing an electronic device precursor and a further aspect relates to an electronic device precursor per se. As discussed herein, the method may manufacture the electronic device precursor described. Equally, the electronic device precursor may be obtained by the method described and any feature described in respect of the method may be applied to the electronic device precursor per se and vice versa. By extension, the description of the method of the first aspect applies equally to the method of the second aspect, unless the context clearly dictates otherwise.

A precursor is intended to refer to a component which is capable of being installed into an electrical or electronic circuit, typically by wire bonding to further circuitry or by other methods known in the art. Thus, an electronic device is a functioning device which provides current to the precursor when installed and during operation.

In a first step, the method comprises providing a substrate having a graphene layer structure on and across a surface thereof. It is particularly preferred that the graphene layer is formed by CVD directly on the substrate. As described herein, it is preferred that the substrate is an insulator and/or semiconductor substrate and particularly preferred that the substrate provides a non-metallic surface upon which the graphene is formed.

Graphene is a very well-known two-dimensional material referring to an allotrope of carbon comprising a single layer of carbon atoms in a hexagonal lattice and may therefore be referred to as a graphene monolayer, which may be doped or undoped. A monolayer of graphene has unique electronic properties associated with the “Dirac cone” band structure of a single graphene sheet. A graphene layer structure consists of from 1 to 10 graphene monolayers, for example multi-layer graphene may be preferred and consists of 2 to 5 graphene monolayers, and 2 or 3 are more preferable. Unless clearly indicated to the contrary, graphene as used herein refers to a graphene layer structure. A single graphene layer is nevertheless particularly preferred since monolayer graphene is a zero band gap semiconductor (i.e. a semi-metal) wherein the density of states at the Fermi level is zero and lies and the point where the top of the valence band meets the bottom of the conduction band (forming a Dirac cone). Due to the low density of states near the Dirac point, a shift in the Fermi level is particularly sensitive to charge transfer into such pristine graphene. The electronic structure also gives rise to, for example, the quantum Hall-effect. For certain embodiments, especially the Hall-sensor configurations described herein, a graphene monolayer is therefore preferable and benefits greatest from the present invention.

The method comprises forming a first layer of dielectric material on and across the graphene layer structure by ALD. Typically, the graphene layer structure having been formed by CVD extends across the entire surface of the wafer, and the first layer is also provided on (which is used herein to mean directly on) the graphene layer structure and across the entire surface graphene layer structure. However, it is sufficient for the first layer to be formed across the entire area of the graphene to be incorporated into the final device precursor, though a benefit of the invention is that mass manufacture “wafer scale” fabrication of an array of electronic precursors is possible and the entire surface is coated.

Preferably, the first layer of dielectric material (and/or the second layer of dielectric material) is an inorganic oxide, nitride or sulfide, for example one or more of the metal oxides Al₂O₃, ZnO, TiO₂, ZrO₂, HfO₂, MgAl₂O₄, and YSZ, preferably alumina (Al₂O₃) or hafnia(HfO₂ ), these materials being particularly suited for ALD.

ALD is technique known in the art and comprises the reaction of at least two precursors in a sequential, self-limiting manner. Repeated cycles to the separate precursors allow the growth of a thin film in a conformal manner (i.e. uniform thickness across the entire substrate, the surface of the graphene layer structure in the present method) due to the layer-by-layer growth mechanism. Alumina is a particularly preferred coating material and can be formed by sequential exposure to trimethylaluminium (TMA) and an oxygen source, preferably one or more of water (H₂O), O₂, and ozone (O₃). ALD is particularly advantageous because a coating may be formed reliably over the entire substrate (i.e. provides a conformal coating).

The inventors were particularly surprised to find that by depositing the first layer of dielectric material by ALD, as opposed to other known methods such as the deposition of a metal layer and auto-oxidation to form a metal oxide dielectric layer, a device with improved properties can be obtained. In particular, the sensitivity of the resulting device is much greater when compared to known methods and, in combination with the further, second layer of dielectric material, the highly sensitive graphene layer structure is also prevented from contamination thereby avoiding loss in the desirable electronic properties.

Preferably, the ALD uses ozone as an oxygen precursor. Preferably, the ozone is provided as a mixture with oxygen, preferably in a concentration of 5 to 30 wt. % (i.e. of the oxygen precursor), more preferably 10 to 20 wt. %. The inventors were also surprised to find that, contrary to common ALD methods, it is beneficial when forming the first dielectric layer by ALD directly on the graphene for the ALD to be performed at a temperature of less than 120° C., more preferably less than 100° C. Those skilled in the art invariably perform ALD at higher temperatures than those which the inventors found to be advantageous. The inventors have found that the use of ozone and/or the low temperature, especially both, provide an advantageous method for improving the electronic properties of the graphene in the final product. Even more specifically, the combination is advantageous for graphene formed directly on the substrate by CVD as described herein. Such graphene which has not been subject to a transfer process, such as from a catalytic metal substrate, does not suffer the same imperfections and defects resulting from the physical manipulation. These defects act as nucleation sites for growth of the dielectric material by ALD whereas, when formed directly on the substrate, there are substantially fewer, if any, defects. The inventors found the conditions described are those which are most preferred for ALD in the absence of the defects and impurities for nucleation.

Suitable precursors which provide the required inorganic element, such as the preferred aluminium or hafnium atoms for alumina and hafnia, are well-known, commercially available and not particularly limited. Metal halides such as metal chlorides (e.g. AlCl₃ and HfCl₄) may be used. Alternatively, metal amides, metal alkoxides or organometallic precursors may be used. Hafnium precursors include, for example, tetrakis(dimethylamido)hafnium(IV), tetrakis(diethylamido)hafnium(IV), hafnium(IV) tert-butoxide and dimethylbis(cyclopentadienyl)hafnium(IV). Preferably, the barrier layer is alumina and preferably a further precursor for the ALD is a trialkyl aluminium or trialkoxide aluminium, such as trimethylaluminium, tris(dimethylamido)aluminium, aluminium tris(2,2,6,6-tetramethyl-3,5-heptanedionate) or aluminium tris(acetylacetonate).

Without wishing to be bound by theory, it is believed that by depositing the first layer by ALD, particularly under the conditions described, the electronic properties of the device are improved at least by virtue of the preferable charge carrier density of the graphene layer structure. Preferably, the graphene layer structure has a charge carrier density of less than 1×10¹² cm⁻², preferably less than 5×10¹¹ cm⁻². As will be appreciated, such values are given without any gate voltage (i.e. 0 V) under ambient conditions (e.g. room temperature at about 20° C.). The inventors have found that the ALD precursors and temperatures can be selected so as to counteract the doping of the graphene layer structure. In some embodiments, particularly for cryogenic temperature applications as described herein, the charge carrier density is preferably greater than 1×10¹² cm⁻², or greater than 3×10¹² cm⁻², and/or less than 8×10¹² cm⁻², for example from 4×10¹² cm⁻² to 6×10¹² cm^{-2.}

As will be appreciated, the first layer of dielectric material may be formed of two or more sub-layers of dielectric material. For example, in some particularly preferred embodiments, the first layer is formed of two layers of dielectric material, each formed by ALD. In some preferred embodiments, the first layer comprises two sub-layers of dielectric material, each formed of the same material such as alumina. Each sub-layer may be formed under different deposition conditions. Preferably, the lower sub-layer, which is deposited before the upper sub-layer, is formed by ALD at a lower temperature than the upper sub-layer. Preferably, it is the lower sub-layer that is deposited at temperatures as described hereinabove for the first layer and/or is deposited using ozone.

The upper sub-layer may be deposited at a temperature of 100° C. or more, preferably 120° C. or more. The upper sub-layer may be formed using the equivalent deposition conditions as those for the ALD of the second layer of dielectric material. Preferably, the upper sub-layer is formed using H₂O as an oxygen precursor. Deposition by ALD at higher temperatures and/or using water as a precursor typically results in a dielectric layer having higher density. Accordingly, even where the same material is used, sub-layers may be readily detected in resulting products using conventional techniques in the art such as cross-section scanning tunnelling microscopy. Without wishing to be bound by theory, is it believed that the use of at least two-sub layers for the first layer of dielectric material can provide a more robust device. In particular, the inventors have found that blisters may form which can damage the “one-dimensional” connection between the graphene and the ohmic contact(s). These blisters are believed to result from trapped gases which remain from the deposition processes. This is a particular problem for devices for use at non-ambient temperatures whereby temperature cycling may induce liberation of the trapped gasses. In particular, the use of ozone during ALD has been observed to give rise to such a problem (whilst this may be a preferred embodiment so as to influence the charge carrier density and the problem may be addressed with the use of the further layers described herein). The method of producing the precursor may then preferably comprise a degassing step to remove such gases during production. This may result simply from the deposition of a further layer (e.g. the upper layer) which critically occurs before the photolithography steps and the deposition of ohmic contacts (and the second layer of dielectric material).

Formation of the first layer of dielectric material may in some embodiments also comprise a first step of depositing a layer of dielectric transition metal oxide as a seed layer, the transition metal oxide having a high work function, for example 6 eV or more, more preferably 6.5 eV or more. A seed layer is typically incomplete or contains pores, permitting the ALD-grown layer to be formed directly on the graphene around the seed layer portions. Work functions of known and available metal oxides are typically no greater than 8 eV, or even 7.5 eV. For example, suitable transition metal oxides may be selected from the group consisting of: molybdenum oxide (e.g. MoO₃, MoO₂), chromium oxide (e.g. CrO₃, Cr₂O₃), vanadium oxide (V₂O₅), tungsten oxide (WO₃), nickel oxide (NiO), cobalt oxide (Co₃O₄), copper oxide (CuO), silver oxide (AgO), titanium oxide (TiO₂), tantalum oxide (Ta₂O₅), and mixtures thereof; preferably molybdenum oxide (e.g. MoO₃), chromium oxide (e.g. CrO₃), vanadium oxide, tungsten oxide, nickel oxide, and mixtures thereof. MoO₃ is most preferred. The addition of such transition metal oxide has been found to afford significantly improved temperature stability to the final device to allow the device to be used in high temperature applications in combination with the layer(s) described above deposited by ALD thereon. Moreover, the inventors have found that the final device may be used at cryogenic temperatures, for example, less than 120 K. In particular, the present disclosure is concerned with the operation of devices at cryogenic temperatures no greater than: 20 K, 10 K, 5 K, 4 K, 3 K, 2 K, 1.5 K, or 1 K. The device may also be suitable for use at millikelvin temperatures (i.e. less than 1 K). In some embodiments, for example for a Hall-sensor, the device may exhibit a substantially linear temperature dependence across a wide magnetic field range, such as from −1 to +1 T, from −7 to +7 T, preferably from −14 to +14 T. In some embodiments, the Hall-sensor may exhibit a non-linearity error from a linear fit of 1% or less, preferably 0.1% or less, as measured between −1 and +1 T.

The transition metal oxide seed layer may have a thickness of from 0.1 nm to 5 nm, preferably up to 2 nm. The desired nominal thickness can be achieved through use of a Quartz Crystal Microbalance (QCM) during formation which provides the skilled person with an in-situ measurement of the amount of material deposited when carrying out the method. The thickness of the layer is therefore a mean average thickness of the layer.

ALD, particularly when using ozone, can serve to functionalise exposed portions of the graphene layer structure having the seed layer thereon (which typically arises where the thickness is 2 nm or less). Ozone also serves to p-dope the graphene layer structure, though the inventors have found that in the absence of the transition metal oxide, the ozone p-doping is less stable on heating. For example, an alumina layer deposited by ALD onto bare graphene using ozone as a precursor can provide excellent sensitivity in the final sensor, though fails to also enhance thermal stability. Whilst the substrate is not particularly limited, the inventors have found that c-plane sapphire is a preferred substrate since a graphene layer structure formed directly on the c-plane surface by CVD has a charge carrier density that is more readily countered by the ALD method described herein. By extension, it is preferred that the substrate is selected so that the charge carrier density of the graphene layer structure formed by CVD is sufficient to counteract the doping resulting from the formation of the first dielectric material thereon. For these reasons, the claimed method is particularly suited for sensor precursors, such a Hall-sensors, since these products benefit greatly from the low charge carrier density.

### First Method

The method further comprises forming a first patterned resist on the first layer of dielectric material to provide at least one protected region of dielectric material and underlying graphene, and at least one unprotected region of dielectric material and underlying graphene. Such a step comprises standard photolithographic techniques in the art. That is, a first resist is coated on and across the first layer. A photoresist (known simply as a resist) is a light-sensitive material. For example, PMMA (polymethylmethacrylate) is a known industry standard whereby the allyl monomer is spin coated across the surface and polymerised is desired portions by exposure to light sufficient to initiate the polymerisation (typically UV light). The unpolymerised material is then removed, such as by washing with a solvent. This provides at least one patterned region of resist and exposes the remaining areas to provide at least one region which does not have resist thereon. Protected therefore serves to refer to the regions upon which the resist is present and allows the subsequent etching, and it will be appreciated that the resist is resistant to etching thereby protecting the underlying dielectric and graphene. Unprotected regions have no resist on the surface of the first layer of dielectric material.

Preferably, the method comprises forming an array of protected regions, each corresponding to an electronic device precursor. Where an array of protected regions are patterned on the layer structure, this typically affords a single continuous unprotected region separating the protected regions though may itself then define an array of unprotected regions. In a preferred embodiment, only one unprotected region is formed during the patterning step since the step of etching as described herein then results in the formation of a continuous outer edge surface of the underlying layers for each electronic device precursor (i.e. the formation of a “filled” “2D shape” with an outer edge such as a rectangle). However, in some embodiments, the 2D shaped and patterned dielectric may have an uncovered portion therein providing an inner and outer edge to the underlying layers after etching (i.e. the formation of a ring, preferably a circular ring, i.e. annular).

The patterning of the first resist serves to define the shape of the dielectric material and graphene layer structure which remains to form part of the resulting electronic device precursor. Preferred electronic device precursors are those for forming a transistor or a Hall-sensor. Other preferred electronic device precursors include those of an electro-optic modulator, photodetector, solar cell, LED/OLED and magnetoresistive sensor. Suitable shapes for the “active channel” of the device, i.e. the patterned dielectric-material-capped graphene layer structure comprising a first dielectric material on a graphene layer structure on the substrate as described herein, are well-known for such devices and are not particularly limited.

In one embodiment, the step of forming the first patterned resist comprises forming one or more rectangular-shaped regions of the resist and wherein the electronic device precursor is for forming a transistor. In a preferred embodiment, the method comprises forming one or more cross-shaped regions of the resist and the electronic device precursor is therefore for forming a Hall-sensor. Preferred shapes for Hall-sensors are well known, preferably it is cross-shaped or Hall-bar shaped, preferably with C2 or C4 rotational symmetry, preferably C4 rotational symmetry (whereby the rotational axis is that orthogonal to surface).

After having patterned the first resist to provide the protected and unprotected region(s), the method then comprises etching away the at least one unprotected region to expose one or more corresponding portions of the substrate and thereby define at least one region of dielectric-material-capped graphene layer structure having one or more exposed edges. Any conventional etching process may be used. Preferably, the unprotected region is etched to remove the unprotected region of the first layer of dielectric material, which as described herein is typically an inorganic oxide, the resist typically being an organic polymer. Preferably, the unprotected dielectric is etched and removed by reactive ion etching (REI) which is a known type of dry etching. Such etching may be sufficient to remove the underlying graphene in the unprotected regions. Accordingly, it is preferred to plasma etch to remove any remaining residue of graphene (such as carbon fragments). Alternatively, a dielectric specific etch may be carried out and plasma etching is carried out in a subsequent step to remove the underlying graphene. Preferably, the plasma etching is oxygen plasma etching. The combination of a dielectric patterned by photolithography, and etching to define the shape provides a patterned dielectric-material-capped graphene layer structure with a highly defined edge (the two layers also therefore share a common edge as a result, i.e. the graphene is capped by the dielectric). Such a method is again particularly suitable for Hall-sensors because of the complex shapes which are more problematic to provide using other known methods.

Such a method was also found to further avoid contamination of the graphene and its edges when compared to using harsh etchants which are typically used in the art, such as a BOE and/or HNO₃/H₂O₂.

At this stage, the first patterned may be removed before application of a second patterned resist. Though, in some embodiments, the first resist is retained thereby ensuring a co-terminal edge is retained by the stack of graphene, dielectric and first resist. The method then comprises forming a second patterned resist on or over the regions of dielectric-material-capped graphene layer structure and on sub-portions of the exposed portions of the substrate to define contact portions adjacent the one or more exposed edges. Such a step is again carried out using standard photolithographic techniques known to those skilled in the art. As will be appreciated, where the first resist in not removed before forming the second patterned resist, the second resist is applied over the protected regions of dielectric and graphene and therefore on the first resist. Where the first resist is removed beforehand, the second resist is formed directly on said regions.

In either case, the second resist is patterned on sub-portions of the exposed portions of the substrate, the substrate having been exposed by the removal of the graphene layer structure. The patterning defines unprotected sub-portions of the substrate directly adjacent the one or more exposed edges of the graphene layer structure. By contact portions, it is meant portions designed to receive a material suitable to provide an ohmic contact with the graphene edge. Thus, the method further comprises forming ohmic contacts in the contact portions. Preferably, the ohmic contact(s) are metal contacts, preferably comprising one or more of titanium, aluminium, chromium and gold. The contacts may be formed by any standard technique, for example by physical vapour deposition such as electron beam deposition.

The method then comprises exposing the dielectric material of the dielectric-material-capped graphene layer structure portions by removing substantially all resist material. This is also known as a conventional lift-off process (which may also include the general steps of forming the second resist and depositing contacts). Typically, this involves washing with a solvent to dissolve the resist material(s). Any layers deposited on the resist (such as excess metal from contact deposition) are also washed from the device.

### Second Method

In a second method, the shape of the patterning of the first dielectric and graphene provides one protected region of dielectric material and underlying graphene, and a plurality of unprotected regions of dielectric material and underlying graphene. This protected region may be referred to as the first protected region in view of the later steps which involve forming at least one protected region to define the shape of the final product(s), which may then be referred to as at least one second protected region.

As with the first method, the first unprotected regions are etched to expose the underlying substrate and therefore multiple edges of the graphene layer structure (i.e. contact portions). Ohmic contacts are then formed in the contact portions, the difference with the first method being the order in which the graphene is patterned into the final device pattern and the deposition of the contacts. A lift off process removes the first photoresist and excess metal deposited thereon to leave the ohmic contacts in the contact portions.

The method comprises forming a second patterned resist on the first region of dielectric-material-capped graphene layer structure, which after patterning may also extend to cover the ohmic contacts, to provide at least one (second) protected region of dielectric material and underlying graphene adjacent a plurality of the ohmic contacts, and at least one (second) unprotected region of dielectric material and underlying graphene. The at least one protected region abuts the ohmic contacts so as to retain the edge contact of the graphene with the ohmic contact deposited in the previous steps. The unprotected regions preferably also abut the ohmic contacts so as to remove in the second etching step all of the graphene that does not form part of the final device precursor.

Accordingly, the method further comprises a second etching step to remove the second unprotected regions of dielectric material and underlying graphene. This step then defines the shape of the dielectric-material-capped graphene layer structure for the device which is the same shape as patterned in the first steps of the first method. The second patterned photoresist is then removed to expose the protected regions of dielectric material arriving at the same intermediate produced by the first method prior to formation of the second layer of dielectric material.

### Both Methods

Finally, the methods comprise forming a second layer of dielectric material on and across the at least one region of dielectric-material-capped graphene layer structure, the ohmic contacts and at least an adjacent portion of the substrate (i.e. all portions adjacent the dielectric capped graphene so as to protect the graphene edges from contamination), preferably the entire substrate. The second layer of dielectric material therefore provides a continuous air-resistant coating. The coating layer may be patterned so as to leave a portion of the contact exposed for connection to a circuit, for example by a physical vapour deposition method such as e-beam evaporation through a shadow mask or by further photolithography and etching.

The air-resistant coating may be referred to as a hermetic coating. The coating may be characterised by an oxygen transmission rate of less than 10⁻¹ cm³/m²/day/atm, preferably less than 10⁻³ cm³/m²/day/atm and more preferably less than 10⁻⁵ cm³/m²/day/atm. The air-resistant coating may also be characterised by a water vapour transmission rate of less than 10⁻² g/m²/day, preferably less than 10⁻⁴ g/m²/day, more preferably less than 10⁻⁵ g/m²/day. Such transmission rates are generally accepted in the art as necessary for use in electronic devices such as LEDs wherein the more preferred transmission rates are necessary for OLEDs and Hall-sensors.

Preferably, the second layer is also formed by ALD since this provides a highly uniform protective coating due to the conformal growth mechanism from all surfaces. On the other hand, PVD methods can suffer from directionality issues which can be addressed by rotating the substrate during deposition. Nevertheless, ALD provides a more robust layer which is advantageous for the present invention to maintain the desirable electronic properties of the graphene which is serves to protect. Preferably, the second layer comprises additional layers. For example, in one preferred embodiment, a silicon nitride (Si₃N₄) layer is deposited on the ALD layer by PECVD to provide further encapsulation.

The inventors have found that a layer formed by PVD keeps the streets clear for dicing (when an array has been manufactured on a common substrate) and also permits keeping a portion of the contact exposed for connection into an electronic circuit. It is also then necessary to puncture the ALD layer in order to wire bond the contacts with metal wire. Despite these drawbacks, the uniformity of the dielectric layer formed by ALD is preferred. Preferably, in order to address these drawbacks, the second layer of dielectric material may be patterned by photolithography to remove the material in the regions of the ohmic contacts and/or the streets to provide easier dicing and/or contacting. Moreover, the coating layer is less likely to be damaged which is advantageous.

### Electronic Device Precursor

In further aspect, the present invention provides an electronic device precursor comprising:
a substrate;
a patterned dielectric-material-capped graphene layer structure comprising a first dielectric material on a graphene layer structure on the substrate;
ohmic contacts on the substrate, each ohmic contact adjacent an edge of the patterned dielectric-material-capped graphene layer structure; and
a second dielectric material on and across the patterned dielectric-material-capped graphene layer structure, the ohmic contacts, and at least an adjacent portion of the substrate;
wherein the patterned dielectric-material-capped graphene layer structure has an area of 20 mm² or less.

Preferably, the substrate comprises silicon (Si), silicon carbide (SiC), silicon nitride (Si₃N₄), silicon dioxide (SiO₂), sapphire (Al₂O₃), aluminium gallium oxide (AGO), hafnium dioxide (HfO₂), zirconium dioxide (ZrO₂), yttria-stabilised hafnia (YSH), yttria-stabilised zirconia (YSZ), magnesium aluminate (MgAl₂O₄), yttrium orthoaluminate (YAlO₃), strontium titanate (SrTiO₃), cerium oxide (Ce₂O₃), scandium oxide (Sc₂O₃), erbium oxide (Er₂O₃), magnesium difluoride (MgF₂), calcium difluoride (CaF₂), strontium difluoride (SrF₂), barium difluoride (BaF₂), scandium trifluoride (ScF₃), germanium (Ge), hexagonal boron nitride (h-BN), cubic boron nitride (c-BN) and/or a III/V semiconductor such as aluminium nitride (AlN) and gallium nitride (GaN). Preferably at least the surface on which the graphene is provided is a material selected from the group (such as for a silicon substrate having a surface for the graphene formed of such material), and in some embodiments, the substrate consists of one material. Preferably, the substrate comprises silicon, silicon nitride, silicon dioxide, sapphire, aluminium nitride, YSZ, germanium and/or calcium difluoride. Preferably, the substrate is sapphire, preferably c-plane sapphire. As will be appreciated, a silicon substrate may include a CMOS substrate which is a silicon based substrate whereby graphene is deposited on a silicon surface, though a CMOS substrate may include various additional layers or circuitry embedded therein.

Preferably, the thickness of the first dielectric material is greater than 5 nm, preferably greater than 10 nm and/or less than 100 nm. The inventors found that the minimum thickness provided a protected graphene layer structure having improved mobility which enables the production of more sensitive devices/sensors. In particular, the provision of the first dielectric material layer as described has been found to provide an improvement in the mobility of at least 2-fold and in some embodiments up to 4-fold (cm²/V).

The electronic device precursor comprises on or more ohmic contacts on the substrate, each ohmic contact adjacent an edge of the patterned dielectric-material-capped graphene layer structure. That is, the contact is in direct contact with the substrate and an edge of the graphene layer structure and, in view of the dielectric material cap, not in contact with a surface of the graphene layer structure.

The second dielectric material is on and across the patterned dielectric-material-capped graphene layer structure, the ohmic contacts, and at least an adjacent portion of the substrate, preferably the entire substrate. Preferably, the thickness of the second dielectric material is greater than 10 nm, preferably greater than 25 nm and more preferably greater than 50 nm. There is no specific upper limit though thicknesses of greater than 10 μm, or greater than 1 μm may only provide limited further protective properties whilst simply increasing the weight and thickness of the device precursor. Additionally, deposition rates by ALD for example can be a slow process and thicker coatings would unduly extend the manufacturing time. Accordingly, an ALD layer thickness of up to 500 nm is also preferable.

As described herein, preferably the graphene layer structure having the dielectric material cap has a charge carrier density of less than 1×10¹² cm⁻², preferably less than 5×10¹¹ cm⁻². Preferably, the electronic device is for forming a Hall-sensor.

The electronic device precursor of this further aspect is a generally “small” device. That is, the size of the “active channel”, the patterned dielectric-material-capped graphene layer structure, is less than 20 mm² (i.e. as measured from a plan view of the device precursor, essentially it is the size of the shape of the first patterned resist which may be used to manufacture the device precursor). The inventors have devised alternative methods which are suitable for manufacturing electronic device precursors that are larger, wherein the graphene layer structure that is present typically has an area of greater than 50 mm². The inventors found that, despite the problems associated with photolithographic techniques in the processing of graphene, the use of a first layer of dielectric material formed by ALD, they were able to use these techniques to produce the small devices.

Smaller devices allow for the production of a greater number across a single wafer/substrate which is essential for the mass production of electronic devices. Additionally, the overall device size after the protective coating is applied is much smaller allowing the device to be used in physically smaller spaces of pre-existing apparatuses. Furthermore, for sensors for example, the smaller active area of the device increases spatial resolution which is key when mapping a magnet or gradient field. Multiple sensors may also be arranged in smaller spaces at different orientations to get vectors or used for ratiometric measurements or internal calibration with improved resolution.

The “resolution” of the layers formed by photolithography are much improved over other methods (such as PVD through a shadow mask). The inventors found that PVD techniques were preferred for larger devices due to the problems of resolution when depositing patterned dielectric layers with very small area (e.g. less than 20 mm²). Preferably, the patterned dielectric-material-capped graphene layer structure (or simply the graphene layer structure) has an area of 10 mm² or less, more preferably 5 mm² or less. Preferably, a longest dimension of the graphene layer structure is 5 mm or less, preferably 4 mm or less, more preferably 3 mm or less, that is the longest straight line from one edge of the graphene layer structure to another edge thereof.

The first dielectric material on the graphene layer structure is preferably obtainable by ALD. Similarly, it is particularly preferred that the graphene layer structure is formed on the substrate by CVD.

Preferably, the graphene layer structure is formed by CVD directly on the non-metallic surface of a substrate. CVD refers generally to a range of chemical vapour deposition techniques, each of which involve vacuum deposition to produce thin film materials such as two-dimensional crystalline materials like graphene. Volatile precursors, those in the gas phase or suspended in a gas, are decomposed to liberate the necessary species to form the desired material, carbon in the case of graphene. CVD as described herein is intended to refer to thermal CVD such that the formation of graphene from the decomposition of a carbon-containing precursor is the result of the thermal decomposition of said carbon-containing precursor. One of the most common precursors for graphene growth is methane though other hydrocarbons may be used. Preferred compounds include those disclosed in UK Patent Application No. 2103041.6 (the contents of which is incorporated herein in its entirety) where it is preferred that the precursor is an organic compound comprising at least two methyl groups (—CH₃). The inventors have found that when forming graphene directly on non-metallic substrates, precursors beyond the traditional hydrocarbons methane and acetylene allow for the formation of even higher quality graphene, and by extension, doped graphene for use in the present invention. Preferably, the precursor is a C₄-C₁₀ organic compound, more preferably the organic compound is branched such that the organic compound has at least three methyl groups. Doped graphene is formed from a carbon-containing precursor which also contains the doping element. Alternatively, a further precursor containing the doping element may be introduced simultaneously with the carbon-containing precursor (and may be carbon-containing itself).

Preferably, the method involves forming graphene by thermal CVD such that decomposition is a result of heating the carbon-containing precursor. Preferably, the CVD reaction chamber used in the method disclosed herein is a cold-walled reaction chamber wherein a heater coupled to the substrate is the only source of heat to the chamber.

In a particularly preferred embodiment, the CVD reaction chamber comprises a close-coupled showerhead having a plurality, or an array, of precursor entry points. Such CVD apparatus comprising a close-coupled showerhead may be known for use in MOCVD processes. Accordingly, the method may alternatively be said to be performed using an MOCVD reactor comprising a close-coupled showerhead. In either case, the showerhead is preferably configured to provide a minimum separation of less than 100 mm, more preferably less than 25 mm, even more preferably less than 10 mm, between the surface of the substrate and the plurality of precursor entry points. As will be appreciated, by a constant separation it is meant that the minimum separation between the surface of the substrate and each precursor entry point is substantially the same. The minimum separation refers to the smallest separation between a precursor entry point and the substrate surface (i.e. the non-metallic surface). Accordingly, such an embodiment involves a “vertical” arrangement whereby the plane containing the precursor entry points is substantially parallel to the plane of the substrate surface.

The precursor entry points into the reaction chamber are preferably cooled. The inlets, or when used, the showerhead, are preferably actively cooled by an external coolant, for example water, so as to maintain a relatively cool temperature of the precursor entry points such that the temperature of the precursor as it passes through the plurality of precursor entry points and into the reaction chamber is less than 100° C., preferably less than 50° C. For the avoidance of doubt, the addition of precursor at a temperature above ambient does not constitute heating the chamber, since it would be a drain on the temperature in the chamber and is responsible in part for establishing a temperature gradient in the chamber.

Preferably, a combination of a sufficiently small separation between the substrate surface and the plurality of precursor entry points and the cooling of the precursor entry points, coupled with the heating of the substrate to with a decomposition range of the precursor, generates a sufficiently steep thermal gradient extending from the substrate surface to the precursor entry points to allow graphene formation on the substrate surface. As disclosed in WO 2017/029470 (which is incorporated herein by reference), very steep thermal gradients may be used to facilitate the formation of high-quality and uniform graphene directly on non-metallic substrates, preferably across the entire surface of the substrate. The substrate may have a diameter of at least 5 cm (2 inches), at least 15 cm (6 inches) or at least 30 cm (12 inches). Particularly suitable apparatus for the method described herein include an Aixtron® Close-Coupled Showerhead® reactor and a Veeco® TurboDisk reactor. Such a method is particularly preferred for enabling the large-scale industrial manufacture of an array of transistors upon a single common substrate. This is particularly advantageous as this allows for consistent device fabrication with stable properties from one device to the next on a commercial scale. Individual devices may be divided therefrom using conventional means such as dicing.

Consequently, in a particularly preferred embodiment wherein the method of the present invention involves using a method as disclosed in WO 2017/029470, the method comprises:
providing a substrate on a heated susceptor in a CVD reaction chamber, the CVD reaction chamber having a plurality of cooled inlets arranged so that, in use, the inlets are distributed across the non-metallic surface of the substrate and have constant separation from the non-metallic surface of the substrate;
cooling the inlets to less than 100° C. (i.e. so as to cool the precursor);
introducing a carbon-containing precursor in a gas phase and/or suspended in a gas through the inlets and into the CVD reaction chamber; and
heating the susceptor to a temperature of at least 50° C. in excess of a decomposition temperature of the precursor, to provide a thermal gradient between the surface of the substrate and inlets that is sufficiently steep to thereby decompose the precursor and allow the formation of a graphene layer structure from the carbon released from the decomposed precursor;

wherein the constant separation is less than 100 mm, preferably less than 25 mm, even more preferably less than 10 mm.

### Cryogenic Applications

Particularly for cryogenic applications, for example, less than 120 K or less than 10 K or at millikelvin temperatures (i.e. less than 1 K), the following embodiments are preferred. A method of producing an electronic device precursor, the method comprising:
(i) providing a substrate having a graphene layer structure on and across a surface thereof;
(ii) forming a first layer of dielectric material on and across the graphene layer structure by ALD;
(iii) forming a first patterned resist on the first layer of dielectric material to provide at least one protected region of dielectric material and underlying graphene, and at least one unprotected region of dielectric material and underlying graphene;
(iv) etching away the at least one unprotected region to expose one or more corresponding portions of the substrate and thereby define at least one region of dielectric-material-capped graphene layer structure having one or more exposed edges;
(v) forming a second patterned resist on or over the region of dielectric-material-capped graphene layer structure and on sub-portions of the exposed portions of the substrate to define contact portions adjacent the one or more exposed edges;
(vi) forming ohmic contacts in the contact portions;
(vii) exposing the dielectric material of the dielectric-material-capped graphene layer structure region by removing substantially all resist material; and
(viii) forming a second layer of dielectric material on and across the at least one region of dielectric-material-capped graphene layer structure, the ohmic contacts and at least an adjacent portion of the substrate,
wherein step (ii) comprises:
   (I) depositing a layer of dielectric transition metal oxide as a seed layer, preferably a MoO₃ seed layer;
   (II) forming a lower sub-layer of dielectric material by ALD, preferably using ozone as an oxygen precursor; and
   (III) forming an upper sub-layer of dielectric material by ALD, preferably using water as an oxygen precursor,
   wherein the lower sub-layer is preferably subjected to a degassing step before formation of the upper sub-layer.

According to a preferred embodiment there is provided an electronic device precursor, preferably an electronic device precursor for forming a Hall-sensor, comprising:
a substrate;
a patterned dielectric-material-capped graphene layer structure comprising a first dielectric material on a graphene layer structure on the substrate;
ohmic contacts on the substrate, each ohmic contact adjacent an edge of the patterned dielectric-material-capped graphene layer structure; and
a second dielectric material on and across the patterned dielectric-material-capped graphene layer structure, the ohmic contacts, and at least an adjacent portion of the substrate;
wherein the patterned dielectric-material-capped graphene layer structure has an area of 20 mm² or less and,
wherein the first dielectric material on a graphene layer structure on the substrate is formed from a lower sub-layer and an upper sub-layer and, preferably comprises a porous seed layer between the graphene layer structure and the lower sub-layer, said porous seed payer preferably comprising MoO₃.

According to a further embodiment there is provided the use of the electronic device precursor, especially as a Hall-sensor, at cryogenic temperatures, as described herein.

### FIGURES

The present invention will now be described further with reference to the following non-limiting Figures, in which:

FIG. 1 illustrates a first method of producing an electronic device precursor in cross sectional view.

FIG. 2 is a plan view of an electronic device precursor obtained by the method shown in FIG. 1.

FIG. 3 illustrates a second method of producing an electronic device precursor in cross sectional view.

FIG. 4 is a condensed illustration of a portion of the method shown in FIG. 1 in plan view.

FIG. 5 is a condensed illustration of a portion of the method shown in FIG. 3 in plan view.

FIG. 6 is a condensed illustration of portions of the methods shown in both FIGS. 1 and 3 in plan view.

FIG. 7 is a plot of Hall resistance (ohms) against magnetic field (T) measured for four Hall-sensor devices, two having a charge carrier density of 4.25×10¹² cm⁻² and two having a charge carrier density of 2.3×10¹² cm⁻².

FIG. 8 is a plot of Hall resistance (ohms) against magnetic field (T) measured for two Hall-sensor devices having a charge carrier density of 4.25×10¹² cm⁻² at both 1.8 K and 300 K.

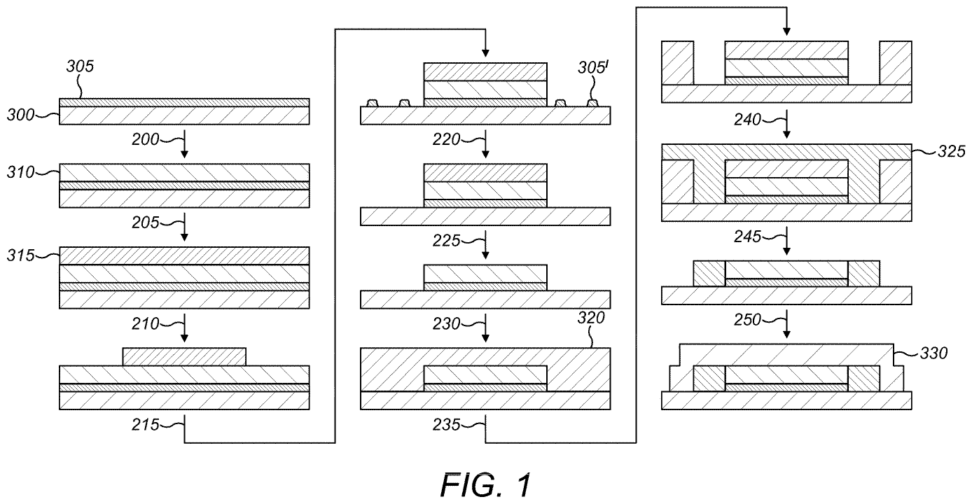

FIG. 1 illustrates a first exemplary method of producing an electronic device precursor. A graphene monolayer 305 is formed directly on a surface of a sapphire substrate 300 by CVD (not shown). A layer of aluminium oxide 310 is then formed 200 on and across the surface of the graphene 305 by ALD using a mixture of oxygen and 15 wt. % ozone as an oxygen precursor, conducted at a temperature of about 80° C. The cycles of oxygen precursor and aluminium precursor are repeated to provide a thickness of about 5 nm resulting in a charge carrier density of less than 5×10¹¹ cm⁻². In other exemplary embodiments, the dielectric layer 310 is formed by the same process and also includes first depositing a seed layer of molybdenum oxide having a nominal thickness of less than 5 nm, and after the ozone ALD, depositing a further layer of aluminium oxide by ALD using H₂O at a temperature of about 150° C. to a total thickness of a first layer of up to about 100 nm.

A first photoresist 315 is applied 205 to the surface of the aluminium oxide layer 310. Conventional photolithography materials and techniques may be used. Typically, a solution containing the photoresist materials is spin coated across the surface. The photoresist materials may comprise polymerisable material (e.g. methyl methacrylate) and patterned/masked UV light is used to cure and polymerise one or more portions of the photoresist materials so as to pattern the photoresist 315 and remove 210 the portions not exposed to UV light to provide at least one protected region.

The exposed unprotected portion of the aluminium oxide 310 and the corresponding underlying portion of the graphene 305 is then etched 215 by reactive ion etching to expose corresponding portions of the substrate and define a region of aluminium oxide 310 capped on the graphene 305 having one or more exposed edges. The step of etching further comprises plasma etching to remove remaining graphene residues 305′ on the substrate surface. The first patterned photoresist 315 is removed by washing with a solvent to provide a patterned stack of aluminium oxide 310 on graphene 305 on the substrate 300. The pattern of the first photoresist therefore defines the pattern of the graphene 305 once etched. The shape is a cross shape suitable for a Hall-sensor that is C4 symmetric. More particularly, the area of the shape is about 10 mm².

A second photoresist 320 is applied 230 to the surface of the patterned stack and on adjacent portions of the substrate 300 which is then patterned 235 on and across the stack and on sub-portions of the exposed portions of the substrate 200. The pattern defines contact portions (i.e. a portion of no photoresist) that is directly adjacent the one or more exposed edges.

Gold metal 325 is then deposited 240 using conventional e-beam methods thereby forming the first and second ohmic contacts in the contact portions. The second patterned photoresist 320 is then removed in a lift-off process 245 which removes the gold 325 deposited thereon leaving behind the first and second ohmic contacts in direct contact with the edge of the graphene 305.

A second layer of aluminium oxide 330 is then formed on and across the patterned stack of alumina-capped-graphene, on the ohmic contacts and on at least an adjacent portion of the substrate thereby encapsulating the layers, in particular, any remaining exposed edges of the graphene 305.

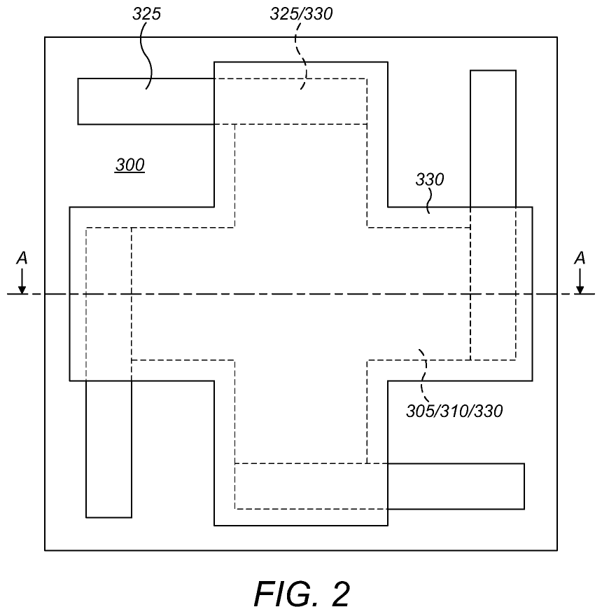

FIG. 2 is a plan view of a Hall-sensor precursor obtainable by the method shown in FIG. 1, with the layers of the precursor shown with transparency to show the underlying layers for clarity. The cross section A-A provides the cross section of the precursor as shown as the final product of FIG. 1. The precursor comprises a sapphire substrate 300 with a cross-shaped graphene monolayer 305 thereon. The graphene 305 has an aluminium oxide cap 310 which was formed by ALD and therefore has the same shape as the underlying graphene 305. The stack of aluminium oxide 310 and graphene 305 share a plurality of edges which define the cross-shape whereby gold contacts 325 are provided as distal portions of the cross, as is conventional in the art, though more specifically, the Hall-sensor precursor comprises gold contacts 325 that are only in contact with an edge of the graphene 305 and not on a surface thereof.

The precursor further comprises an aluminium oxide coating 330 which has a similar cross-shape but larger so as to extend on and across the patterned stack and the adjacent portions of the substrate to protect the edges of the graphene 305. The aluminium oxide coating 330 is also provided on the gold contacts 325 in the region of the graphene 305, though portions of the contacts 325 are exposed for connection to an electrical circuit. In other embodiments, the coating is applied on and across the substrate and connection is made by wire bonding metal wires to the contacts through the coating.

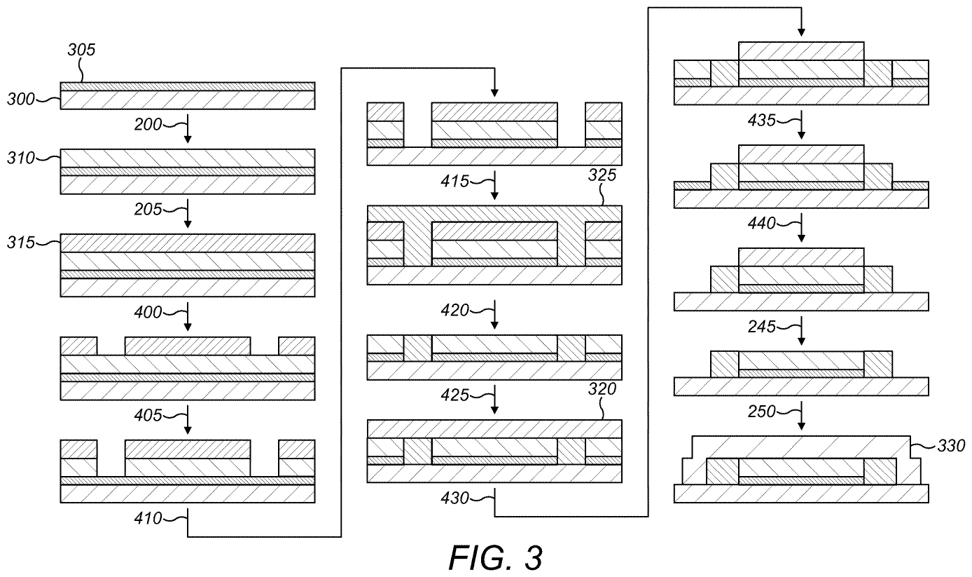

FIG. 3 illustrates a second method of producing an electronic device precursor. A graphene monolayer 305 is formed directly on a surface of a sapphire substrate 300 by CVD (not shown) and a layer of aluminium oxide 310 is then formed 200 on and across the surface of the graphene 305 by ALD using a mixture of oxygen and 15 wt. % ozone as an oxygen precursor, conducted at a temperature of about 80° C. The cycles of oxygen precursor and aluminium precursor are repeated to provide a thickness of about 5 nm resulting in a charge carrier density of less than 5×10¹¹ cm⁻². A first photoresist 315 is applied 205 to the surface of the aluminium oxide layer 310. These steps are identical to those of the first method of FIG. 1 and, as described above, other embodiments may additionally include, in the step of forming the first layer of dielectric material, first forming a MoO₃ seed layer and after the ozone ALD sub-layer, an H₂O ALD sub-layer thereon.

The first photoresist 315 is then patterned 400 using conventional photolithography techniques to remove a plurality of portions of the first photoresist 315 to form a plurality of unprotected regions of the aluminium oxide 310 and underlying graphene 305.

The exposed unprotected regions are then etched 405, 410 by reactive ion etching to expose corresponding portions of the substrate and define a continuous region of aluminium oxide 310 capped on the graphene 305 having a plurality of exposed edges (i.e. which define contact portions. The method may also comprise plasma etching to remove any graphene residues which may remain. Gold metal 325 is then deposited 415 using conventional e-beam methods thereby forming the first and second ohmic contacts in the contact portions. The first patterned photoresist 315 is then removed in a lift-off process 410 which removes the gold 325 deposited thereon leaving behind the first and second ohmic contacts in direct contact with the edge of the graphene 305.

A second photoresist 320 is applied 425 across the surface of the intermediate which is then patterned 430 to provide at least one protected region of the aluminium oxide 310 and the corresponding underlying portion of the graphene 305 and at least one unprotected region (i.e. a portion of no photoresist). The second photoresist 320 may optionally be patterned to cover the ohmic contacts. The patterning of the second photoresist 320 serves to define the pattern of the graphene 305 once etched for the final device precursor (whereas in the first method the first photoresist defines such a pattern).

Etching is then repeated 435, 440 to etch away the exposed regions of the aluminium oxide 310 and the corresponding underlying portion of the graphene 305. Where multiple protected regions of the second photoresist 320 are formed, the etching isolates each intermediate for the electronic device precursor from one another by exposing the adjacent portions of the substrate 300.

The second patterned photoresist 320 is removed by washing with a solvent. Then in accordance with the first method, a second layer of aluminium oxide 330 is then formed on and across the patterned stack of alumina-capped-graphene, on the ohmic contacts and on at least an adjacent portion of the substrate thereby encapsulating the layers, in particular, any remaining exposed edges of the graphene 305.

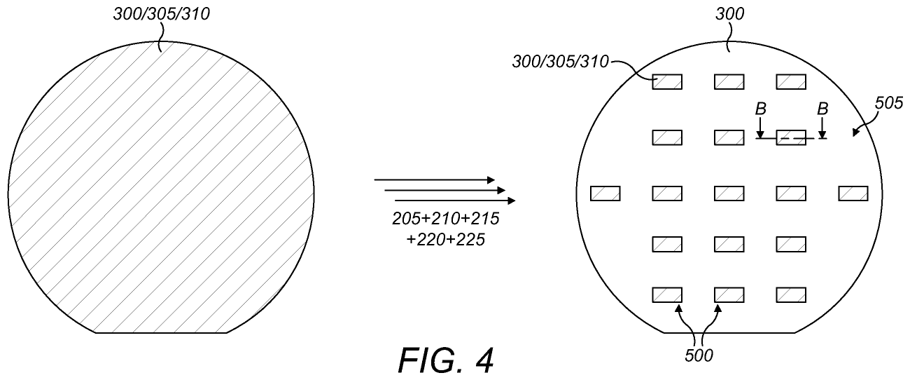

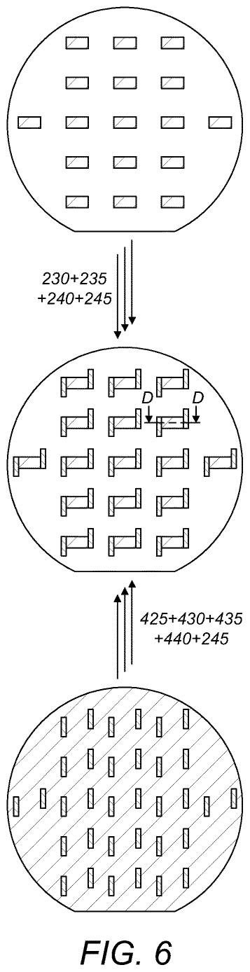

FIG. 4 is a condensed illustration of a portion of the first method as shown in FIG. 1 in plan view. The 5 cm diameter sapphire substrate 300 has the graphene monolayer 305 and aluminium oxide layer 310 provided on an across the entire surface. FIG. 6 illustrates the result of the first photolithography steps 205, 210, 215, 220 and 225 described above when forming a plurality of patterned stacks 500 of aluminium oxide 310 on graphene 305 on the substrate 300. A single continuous exposed portion 505 of the substrate separates the stacks 500. The stacks 500 shown have a rectangular shape and may be used to form a transistor. The cross section B-B provides the cross section of the intermediate as shown after step 225 in FIG. 1.

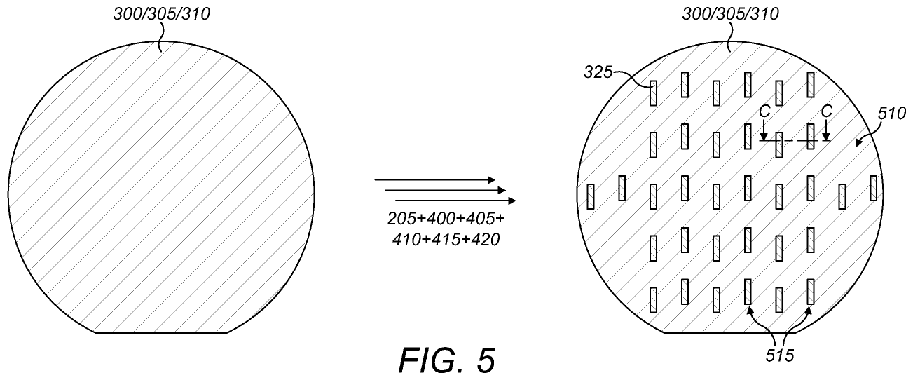

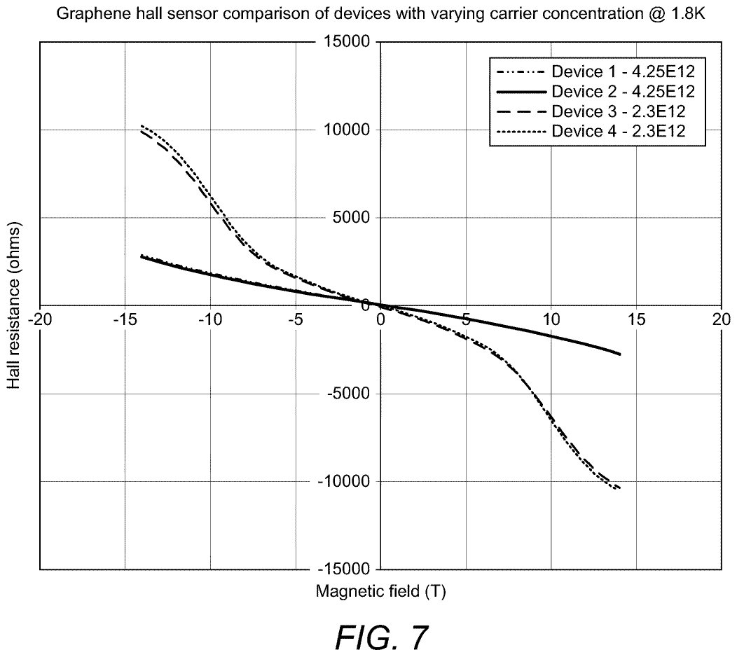

FIG. 5 is a condensed illustration of a portion of the second method as shown in FIG. 3 in plan view. From the same starting point as shown in FIG. 6, FIG. 7 illustrates the result of the first photolithography steps 205, 400, 405, 410, 415 and 420 for forming a continuous region 510 of aluminium oxide 310 of graphene 305, having a plurality of ohmic contacts 325 deposited in a plurality of contact portions 515. The cross section C-C provides the cross section of the intermediate as shown after step 420 in FIG. 3.

FIG. 6 illustrates the second photolithography steps for each of the first and second methods (i.e. 230, 235, 240 and 245; and 425, 430, 435, 440 and 245, respectively) applied to the patterned wafers resulting from the steps shown in FIGS. 6 and 7, to arrive at the same product, an array of transistor precursors (albeit without the second layer of aluminium oxide). In the first method, the second photoresist is used to form the same plurality of ohmic contacts 515 as prepared in the first photolithography steps of the second method. In the second method, the second photoresist is used to form the same plurality of stacks 500 as prepared in the first photolithography steps of the first method. As such, a plurality of rectangular regions are patterned such that each stack retains an edge contact with at least two of the ohmic contacts 325 already having been deposited. The cross section D-D provides the cross section of the intermediate as shown after step 245 in both FIGS. 3 and 5.

Four Hall-sensor devices were produced according to the method described herein. The first two devices have a charge carrier density of 4.25×10¹² cm⁻² and the second two devices have a charge carrier density of 2.3×10¹² cm⁻². Each device is formed of a sapphire substrate, a graphene monolayer and a first dielectric layer cap. The first dielectric layer is formed of 1 nm MoO₃ and 15 nm of alumina formed by ALD and the second layer of dielectric material is a 65 nm alumina layer.

The Hall resistance of these devices were measured across −14 T to +14 T at a cryogenic temperature of 1.8 K. FIG. 7 illustrates that the device having a charge carrier density of 4.25×10¹² cm⁻² exhibits greater linearity in its sensitivity across the full magnetic field measured. On the contrary, the increased sensitivity of the device having a charge carrier density of 2.3×10¹² cm⁻² leads to a stronger quantum hall effect and reduced linearity at 1.8 K.

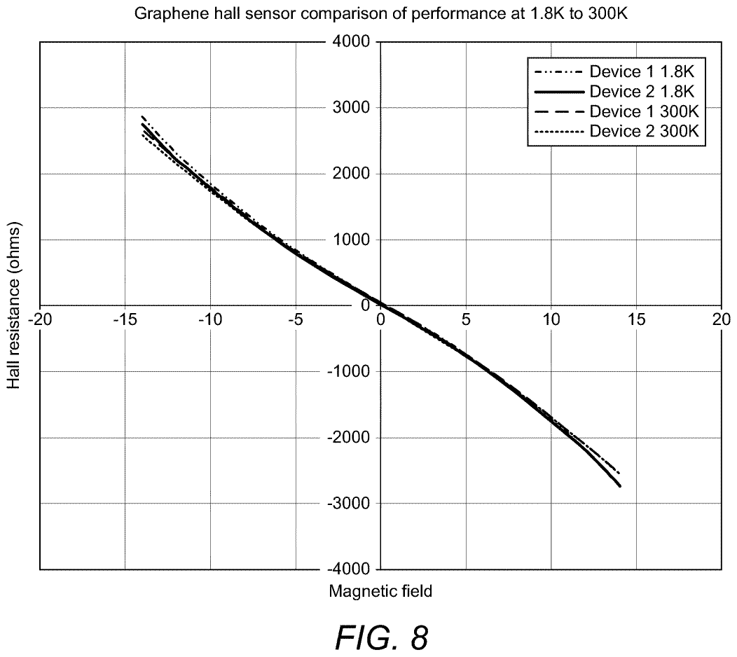

FIG. 8 illustrates the remarkable consistency of sensitivity and device response across a wide temperature range of 1.8 K and 300 K across the magnetic field range of −14 T to +14 T.

As used herein, the singular form of “a”, “an” and “the” include plural references unless the context clearly dictates otherwise. The use of the term “comprising” is intended to be interpreted as including such features but not excluding other features and is also intended to include the option of the features necessarily being limited to those described. In other words, the term also includes the limitations of “consisting essentially of” (intended to mean that specific further components can be present provided they do not materially affect the essential characteristic of the described feature) and “consisting of” (intended to mean that no other feature may be included such that if the components were expressed as percentages by their proportions, these would add up to 100%, whilst accounting for any unavoidable impurities), unless the context clearly dictates otherwise.

It will be understood that, although the terms “first”, “second”, etc. may be used herein to describe various elements, layers and/or portions, the elements, layers and/or portions should not be limited by these terms. These terms are only used to distinguish one element, layer or portion from another, or a further, element, layer or portion. It will be understood that the term “on” is intended to mean “directly on” such that there are no intervening layers between one material being said to be “on” another material. Spatially relative terms, such as “under”, “below”, “beneath”, “lower”, “over”, “above”, “upper” and the like, may be used herein for ease of description to describe one element or feature's relationship to another element(s) or feature(s). It will be understood that the spatially relative terms are intended to encompass different orientations of the device in use or operation in addition to the orientation depicted in the figures. For example, if a device as described herein is turned over, elements described as “under” or “below” other elements or features would then be oriented “over” or “above” the other elements or features. Thus, the example term “under” can encompass both an orientation of over and under. The device may be otherwise oriented and the spatially relative descriptors used herein interpreted accordingly.

The foregoing detailed description has been provided by way of explanation and illustration, and is not intended to limit the scope of the appended claims. Many variations of the presently preferred embodiments illustrated herein will be apparent to one of ordinary skill in the art, and remain within the scope of the appended claims and their equivalents.

1. A method of producing an electronic device precursor, the method comprising:
(i) providing a substrate having a graphene layer structure on and across a surface thereof;
(ii) forming a first layer of dielectric material on and across the graphene layer structure by ALD;
(iii) forming a first patterned resist on the first layer of dielectric material to provide at least one protected region of dielectric material and underlying graphene, and at least one unprotected region of dielectric material and underlying graphene;
(iv) etching away the at least one unprotected region to expose one or more corresponding portions of the substrate and thereby define at least one region of dielectric-material-capped graphene layer structure having one or more exposed edges;
(v) forming a second patterned resist on or over the region of dielectric-material-capped graphene layer structure and on sub-portions of the exposed portions of the substrate to define contact portions adjacent the one or more exposed edges;
(vi) forming ohmic contacts in the contact portions;
(vii) exposing the dielectric material of the dielectric-material-capped graphene layer structure region by removing substantially all resist material; and
(viii) forming a second layer of dielectric material on and across the at least one region of dielectric-material-capped graphene layer structure, the ohmic contacts and at least an adjacent portion of the substrate.

2. The method according to claim 1, wherein between steps (iv) of etching and (v) of forming a second patterned resist, the first patterned resist is removed.

3. A method of producing an electronic device precursor, the method comprising:
(I) providing a substrate having a graphene layer structure on and across a surface thereof;
(II) forming a first layer of dielectric material on and across the graphene layer structure by ALD;
(III) forming a first patterned resist on the first layer of dielectric material to provide one protected region of dielectric material and underlying graphene, and a plurality of unprotected regions of dielectric material and underlying graphene;
(IV) etching away the plurality of unprotected regions to expose corresponding portions of the substrate and thereby define one first region of dielectric-material-capped graphene layer structure having a plurality of exposed edges and to define contact portions adjacent the one or more exposed edges;
(V) forming ohmic contacts in the contact portions;
(VI) exposing the dielectric material of the dielectric-material-capped graphene layer structure region by removing substantially all resist material;
(VII) forming a second patterned resist on the first region of dielectric-material-capped graphene layer structure, and optionally the ohmic contacts, to provide at least one protected region of dielectric material and underlying graphene adjacent a plurality of the ohmic contacts, and at least one unprotected region of dielectric material and underlying graphene;
(VIII) etching away the at least one unprotected region to expose one or more corresponding portions of the substrate and thereby define at least one second region of dielectric-material-capped graphene layer structure having a plurality of exposed edges whereby each ohmic contact remains adjacent an edge of the at least one second region of dielectric-material-capped graphene layer structure;
(IX) exposing the dielectric material of the at least one second region of dielectric-material-capped graphene layer structure by removing substantially all resist material; and
(X) forming a second layer of dielectric material on and across the at least one second region of dielectric-material-capped graphene layer structure, the ohmic contacts and at least an adjacent portion of the substrate.

4. The method according to claim 1, wherein the first layer of dielectric material and/or the second layer of dielectric material is an inorganic oxide.

5. The method according to claim 1, wherein etching comprises reactive ion etching and optionally further comprises a step of plasma etching to remove any remaining residue.

6. (canceled)

7. The method according to claim 1, wherein forming a second layer of dielectric material is by ALD on and across the at least one region of dielectric-material-capped graphene layer structure, the ohmic contacts, and the entire substrate.

8. The method according to claim 1, wherein forming a resist to provide the at least one protected region comprises forming:
(i) one or more rectangular shaped regions of the resist and wherein the electronic device precursor is for forming a transistor; or
(ii) one or more cross-shaped regions of the resist and wherein the electronic device precursor is for forming a Hall-sensor.

9. The method according to claim 1, wherein a longest dimension of the graphene layer structure is 5 mm or less and/or wherein an area of the graphene layer structure is 20 mm² or less.

10. (canceled)

11. The method according to claim 1, wherein the method comprises forming an array of protected regions, each corresponding to an electronic device precursor.

12. The method according to claim 11, wherein the method further comprises a step of dicing the substrate to separate electronic device precursors from the array, after step (viii) of forming a second layer of dielectric material.

13. The method according to claim 1, further comprising a step of wire bonding metal wires to the ohmic contacts through the second layer of dielectric material.

14. An electronic device precursor comprising:
a substrate;
a patterned dielectric-material-capped graphene layer structure comprising a first dielectric material on a graphene layer structure on the substrate;
ohmic contacts on the substrate, each ohmic contact adjacent an edge of the patterned dielectric-material-capped graphene layer structure; and
a second dielectric material on and across the patterned dielectric-material-capped graphene layer structure, the ohmic contacts, and at least an adjacent portion of the substrate;
wherein the patterned dielectric-material-capped graphene layer structure has an area of 20 mm² or less.

15. The electronic device precursor according to claim 14, wherein the electronic device precursor is for forming a Hall sensor.

16. The electronic device precursor according to claim 14, wherein the graphene layer structure is formed on the substrate by CVD.

17. The electronic device precursor according to claim 16, wherein the graphene layer structure has a charge carrier density of less than 1×10¹² cm⁻².

18. The electronic device precursor according to claim 14, wherein the first dielectric material on the graphene layer structure is obtainable by ALD.

19. The electronic device precursor according to claim 17, wherein the first dielectric material on the graphene layer structure is obtainable by ALD, and wherein the substrate is selected so that the charge carrier density of the graphene layer structure formed by CVD is sufficient to counteract the doping resulting from the formation of the first dielectric material thereon.

20. The electronic device precursor according to claim 19, wherein the substrate is c-plane sapphire.

21-22. (canceled)

23. The electronic device precursor according to claim 18, wherein the ALD is performed at a temperature of less than 120° C.

24. (canceled)

25. The electronic device precursor according to claim 14, wherein the thickness of the first dielectric material is greater than 5 nm, and/or less than 100 nm.

26. (canceled)
